(19) United States
(12) Patent Application Publication
(10) Pub. No.: US 2024/0310167 A1
(43) Pub. Date: Sep. 19, 2024

(54) PATTERN SHAPE MEASUREMENT METHOD, PATTERN SHAPE MEASUREMENT DEVICE, AND MANUFACTURING METHOD OF SEMICONDUCTOR DEVICE

(71) Applicant: Kioxia Corporation, Tokyo (JP)

(72) Inventor: Kazuki HAGIHARA, Yokohama Kanagawa (JP)

(73) Assignee: Kioxia Corporation, Tokyo (JP)

(21) Appl. No.: 18/593,000

(22) Filed: Mar. 1, 2024

(30) Foreign Application Priority Data
Mar. 17, 2023 (JP) 2023-043129

(51) Int. Cl. G01B 15/04; G06T 7/00; G06T 7/543; H10B 80/00

(52) U.S. Cl. CPC G01B 15/04; G06T 7/001; G06T 7/543; H10B 80/00; G06T 2207/30148

(57) ABSTRACT

A pattern shape measurement method includes acquiring image data of a target pattern obtained by irradiating an observation region of a sample with a charged particle or an electromagnetic wave, generating first contour point group data in which location information of a contour point of the target pattern extracted based on the image data and an index related to an orientation angle of a line connecting a center of the target pattern and the contour point from a reference line passing through the center of the target pattern are associated with each other, and generating, based on a weighting table in which the index and weight determined based on a standard deviation of location information of the contour point of the target pattern present in a direction of the orientation angle are associated with each other and stored, and the first contour point group data, second contour point group data according to the weight.

### CROSS-REFERENCE TO RELATED APPLICATION

This application is based upon and claims the benefit of priority from Japanese Patent Application No. 2023-043129, filed Mar. 17, 2023, the entire contents of which are incorporated herein by reference.

### FIELD

Embodiments described herein relate generally to a pattern shape measurement method, a pattern shape measurement device, and a manufacturing method of a semiconductor device.

### BACKGROUND

In a semiconductor device, particularly a memory device, a plurality of patterns having the same design may be formed on a substrate. These patterns are required to be finished in the same shape. A technique of measuring a pattern shape based on contour information of a captured image of a pattern acquired by an imaging device or the like is used.

However, the accuracy of the contour information may be lowered because of the variations in the captured image. The decrease in the accuracy of the contour information is a factor that decreases the accuracy of the measurement.

### DESCRIPTION OF THE DRAWINGS

FIG. 1 is a block diagram illustrating an example of a schematic of a shape measurement system according to at least one embodiment.

FIG. 2 is a diagram illustrating an example of a configuration of an electron image capturing device according to the embodiment.

FIG. 3 is a diagram illustrating an example of image data according to the embodiment.

FIG. 4 is a diagram illustrating the specifying of a contour point according to the embodiment.

FIGS. 5A and 5B are diagrams showing an example of first contour point group data according to the embodiment.

FIG. 6 is a diagram illustrating an example of a weighting table according to the embodiment.

FIGS. 7A and 7B are diagrams showing an example of second contour point group data according to the embodiment.

FIG. 8 is a diagram illustrating the calculation of the dimensions according to the embodiment.

FIG. 9 is a block diagram illustrating an example of a hardware configuration of a pattern shape measurement device according to the embodiment.

FIG. 10 is a flowchart showing an example of a procedure of a manufacturing method of a semiconductor device according to the embodiment.

FIG. 11 is a diagram illustrating an example of a procedure of a generating method of the weighting table according to the embodiment.

FIG. 12 is a diagram illustrating a standard deviation of location information of a contour point according to the embodiment.

FIG. 13 is a diagram illustrating the standard deviation in FIG. 12 in a radar chart.

FIGS. 14A and 14B are diagrams illustrating random extraction based on weight in the embodiment.

FIG. 15 is a diagram illustrating an example of a procedure of a pattern shape measurement method according to a modification example.

### DETAILED DESCRIPTION

Embodiments provides a pattern shape measurement method, a pattern shape measurement device, and a manufacturing method of a semiconductor device, which are capable of measuring a pattern shape with high accuracy.

In general, according to one embodiment, a pattern shape measurement method includes acquiring image data of a target pattern obtained by irradiating an observation region of a sample with a charged particle or an electromagnetic wave, generating first contour point group data in which location information of a contour point of the target pattern extracted based on the image data and an index related to an orientation angle of a line connecting a center of the target pattern and the contour point from a reference line passing through the center of the target pattern are associated with each other, and generating, based on a weighting table in which the index and weight determined based on a standard deviation of location information of the contour point of the target pattern present in a direction of the orientation angle are associated with each other and stored, and the first contour point group data, second contour point group data according to the weight.

Hereinafter, an embodiment of the present disclosure will be described in detail with reference to the drawings. Further, the present disclosure is not limited to the following embodiment. Elements according to the following embodiment include those that can be easily assumed by those skilled in the art or those that are substantially the same.

### EMBODIMENT

Hereinafter, the embodiment will be described in detail with reference to the drawings.

### Configuration Example of Shape Measurement System

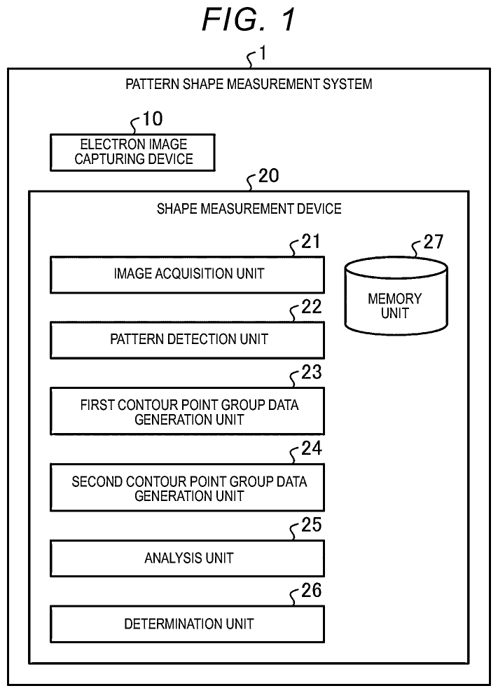

FIG. 1 is a block diagram illustrating an example of a schematic of a pattern shape measurement system 1 according to the embodiment. As shown in FIG. 1, the pattern shape measurement system 1 is provided with an electron image capturing device 10 and a shape measurement device 20.

A target pattern that is a measurement target is formed in a sample S to be observed by the pattern shape measurement system 1 of the embodiment. The pattern shape measurement system 1 is configured as a system that measures a shape of a target pattern based on image data IM obtained by imaging the target pattern.

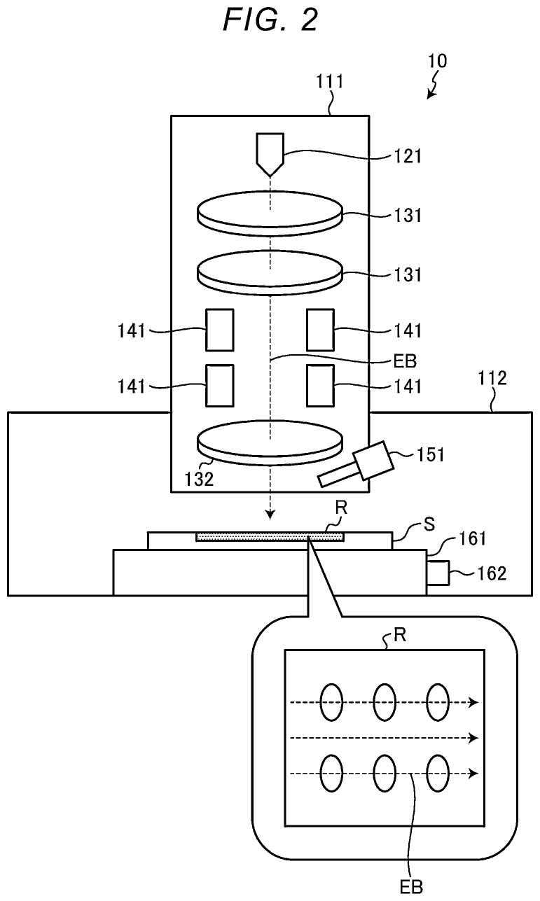

First, the electron image capturing device 10 will be described. Each part of the shape measurement device 20 will be described later. FIG. 2 is a diagram illustrating an example of a configuration of the electron image capturing device 10 according to the embodiment.

The electron image capturing device 10 is an imaging device that is capable of irradiating the observation region R of the sample S with charged particles or electromagnetic waves to capture an image of the target pattern that the sample S has and forming image data IM of the target pattern. The electron image capturing device 10 is configured as, for example, a critical dimension scanning electron microscope (CD-SEM) that is capable of irradiating a sample S with an electron beam EB to form image data IM of a target pattern.

As shown in FIG. 2, the electron image capturing device 10 is provided with a lens barrel 111 on which an electron gun 121 serving as an irradiation source of the electron beam EB is installed, a sample chamber 112 in which a sample S is disposed, and a control unit (not shown) that controls each part of the electron image capturing device 10.

The lens barrel 111 has a cylindrical shape provided with a closed upper end portion and an open lower end portion through which the electron beam EB passes. The sample chamber 112 is capable of accommodating the sample S. The lens barrel 111 and the sample chamber 112 are combined in a state of being airtightly sealed. The inside of the lens barrel 111 and the inside of the sample chamber 112 are capable of being held at a reduced pressure by a pump or the like (not shown).

In the inside of the lens barrel 111, the electron gun 121, a focusing lens 131, an object lens 132, a coil 141, and a detector 151 are installed in order from the vicinity of the upper end portion.

The electron gun 121 emits the electron beam EB toward the lower side in the lens barrel 111. The electron beam EB emitted from the electron gun 121 travels along the longitudinal direction of the lens barrel 111.

The focusing lens 131 is an electromagnetic coil wound concentrically around the optical axis of the lens barrel 111, and focuses the electron beam EB by a magnetic field.

The object lens 132 is an electromagnetic coil wound concentrically around the optical axis of the lens barrel 111, and focuses the electron beam EB emitted toward the sample S by the magnetic field.

The coil 141 is an electromagnetic coil that is a pair of two coils for deflecting the focused electron beam EB or performing astigmatism correction. The coil 141 is disposed symmetrically with respect to the optical axis of the lens barrel 111. The coil 141 scans the focused electron beam EB in a predetermined direction of the observation region R in which the target pattern is formed.

The detector 151 detects the secondary electrons or the backscattered electrons generated from the sample S. The detector 151 images the signal amount of the secondary electrons or the backscattered electrons detected as a result of the observation region R being scanned with the electron beam EB. As a result, image data IM in which the target pattern is imaged is generated.

A stage 161 on which the sample S is placed is provided in the sample chamber 112. An actuator 162 is attached to the stage 161, and the stage 161 is drivable forward and backward and right and left. The image data IM for the desired observation region R can be generated by driving the stage 161.

The electron image capturing device 10 transmits the generated image data IM of the target pattern to the shape measurement device 20.

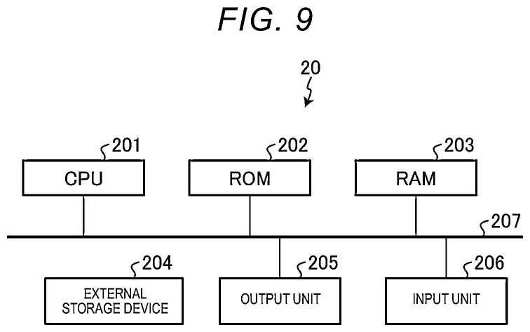

Returning to FIG. 1, the shape measurement device 20 will be described. The shape measurement device 20 serving as the pattern shape measurement device executes shape measurement processing for the target pattern based on the image data IM acquired from the electron image capturing device 10. The shape measurement device 20 is provided with an image acquisition unit 21, a pattern detection unit 22, a first contour point group data generation unit 23, a second contour point group data generation unit 24, an analysis unit 25, a determination unit 26, and a memory unit 27 as functional units for executing shape measurement processing. These functional elements may be provided by the cooperation of hardware and software as shown in FIG. 9 described later, for example.

The image acquisition unit 21 acquires the image data IM of the target pattern from the electron image capturing device 10. The image acquisition unit 21 outputs the acquired image data IM to the output unit 205 of the shape measurement device 20, for example.

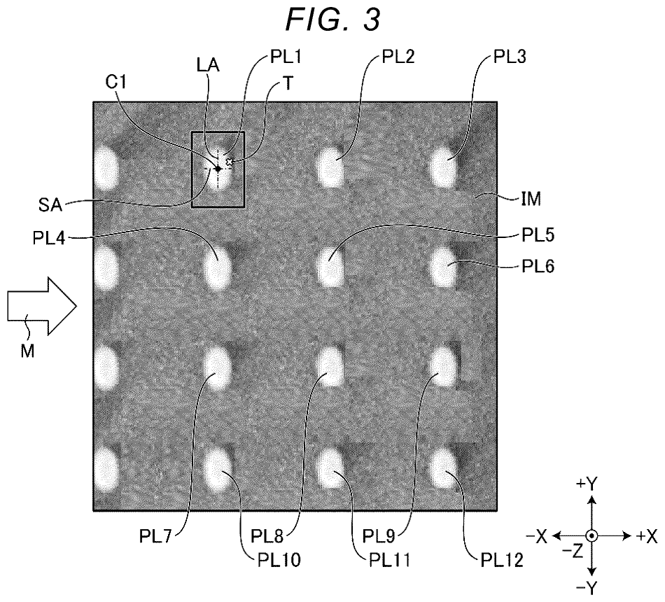

FIG. 3 is a diagram illustrating an example of image data IM according to the embodiment.

In the present specification, for convenience of description, the right-left direction on each drawing is defined as the X-axis, and the up-down direction on each drawing is defined as the Y-axis. In addition, a direction intersecting each of the X-axis and the Y-axis is defined as a Z-axis. In addition, the directions indicated by the arrows of the X-axis, the Y-axis, and the Z-axis are defined as the positive direction of X, the positive direction of Y, and the positive direction of Z, respectively, and the opposite directions of the arrows are defined as the negative direction of X, the negative direction of Y, and the negative direction of Z, respectively.

As shown in FIG. 3, the image data IM includes a plurality of pillars PL1 to PL12 (hereinafter, may be referred to as “pillar PL”). The pillars PL1 to PL12 are pillar patterns formed based on the same design information. Each of the pillars PL1 to PL12 has an elliptical shape having a minor axis SA extending in the X direction and a major axis LA extending in the Y direction, when viewed from the positive direction of Z.

In FIG. 3, an arrow M directed in the positive direction of X corresponds to the scanning direction of the electron beam EB described with reference to FIG. 2. That is, the pillars PL1 to PL12 are scanned in a predetermined direction in which the arrow M in FIG. 3 is directed by the electron beam EB. The scanning direction of the electron beam EB is not limited to the example shown in FIGS. 2 and 3. The scanning direction of the electron beam EB may be different depending on the electron image capturing device 10.

The pillars PL1 to PL12 shown in FIG. 3 are examples and are not limited thereto. For example, the image data IM may include only one pillar PL. Further, a hole pattern may be included in the image data IM instead of the pillar PL.

In the present embodiment, it is assumed that the shape measurement processing of the pillar PL1 as the target pattern is executed among the pillars PL1 to PL12. The measurement of the shape of the pillar PL1 includes, for example, the definition of the dimension CD of the pillar PL1.

The pattern detection unit 22 detects the pillar PL1 based on the image data IM. Specifically, the pattern detection unit 22 performs pattern matching based on the image data IM and the model data including the design information of the pillars PL1 to PL12. As a result, the pillar PL1 that is a measurement target is detected.

The pattern detection unit 22 specifies the center point C1 of the detected pillar PL1 as the center of the target pattern. Specifically, the pattern detection unit 22 performs pattern matching based on the image data IM and the model data. As a result, the location of the pattern center in the model data is specified as the center point C1 of the pillar PL1.

The first contour point group data generation unit 23 specifies the contour point T of the pillar PL1 based on the image data IM. The contour point T is the location for specifying the contour of the pillar PL1 in the image data IM. The dimension CD of the pillar PL is specified based on the location of the contour point T.

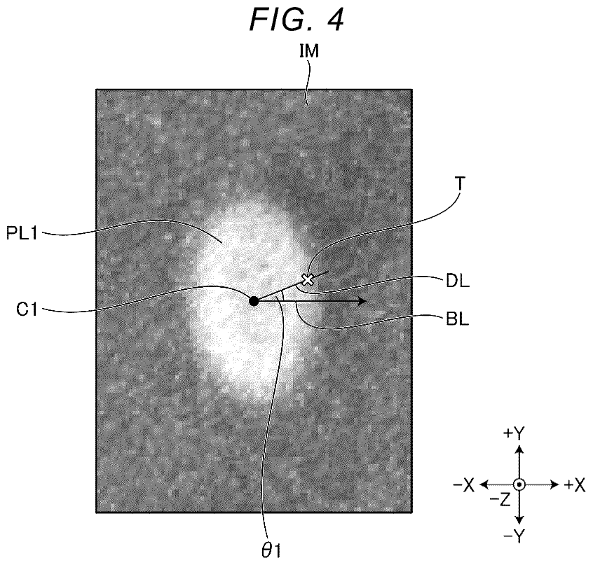

FIG. 4 is a diagram illustrating the specifying of the contour point T according to the embodiment. FIG. 4 is a diagram in which the pillar PL1 in the image data IM in FIG. 3 is enlarged.

Specifically, as shown in FIG. 4, the first contour point group data generation unit 23 defines a reference line BL that passes through the center point C1 of the pillar PL1 and extends along the positive direction of X. The first contour point group data generation unit 23 acquires the grayscale of the pixel on the orientation line DL extending in the direction at the orientation angle θ from the reference line BL, for example, and generates the luminance profile in a radial direction.

The first contour point group data generation unit 23 specifies, for example, a location where the luminance is maximized as the contour point T on the orientation line DL based on the generated luminance profile. Here, the orientation line DL is a line connecting the center point C1 and the contour point T. The first contour point group data generation unit 23 specifies the location information of the contour point T based on the distance from the center point C1 to the contour point T and the orientation angle θ. The location information of the contour point T includes the distance from the center point C1 to the contour point T, the orientation angle θ, and the coordinate information of the contour point Ti.

The first contour point group data generation unit 23 specifies the location information of the contour point T based on each of the orientation lines DL extending in all orientations from the reference line BL.

The first contour point group data generation unit 23 generates the first contour point group data 100 in which each of pieces of the location information of the contour points T specified in all orientations is associated with the index ID.

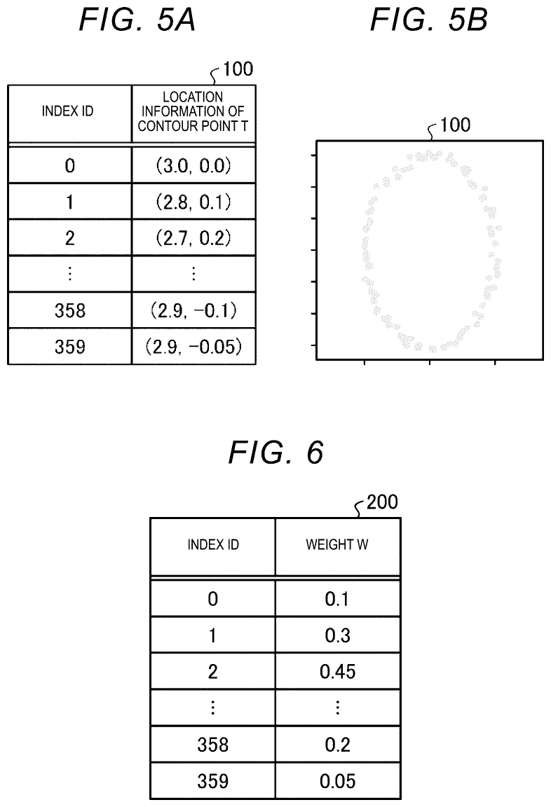

FIGS. 5A and 5B are diagrams showing an example of the first contour point group data 100 according to the embodiment. The example in FIG. 5A represents the first contour point group data 100, in which the pieces of location information of the specified contour points T in all orientations are associated with the indexes ID0 to ID359, in a table. In addition, the example of FIG. 5B represents the first contour point group data 100 of FIG. 5A on the coordinates.

Each of the indexes ID shown in FIG. 5A is associated with each of the orientation angles θ of 0° to 359° defined in 1° increments from the reference line BL with the reference line BL as 0°. As described above, the indexes ID and the orientation angles θ have a corresponding relationship. In other words, the indexes ID are related to the orientation angles θ.

The second contour point group data generation unit 24 generates the second contour point group data 300 according to the weight W based on the generated first contour point group data 100 and a weighting table 200.

The memory unit 27 is a storage medium such as a hard disk drive (HDD) or a solid state drive (SSD). The memory unit 27 stores the weighting table 200.

FIG. 6 is a diagram illustrating an example of the weighting table 200 according to the embodiment. The weighting table 200 shown in FIG. 6 is stored in the memory unit 27.

Here, the weight W is determined based on the standard deviation σ of the location information of the contour point T present in the direction at the orientation angle θ from the reference line BL. For example, when a plurality of pieces of image data IM with the same pillar PL1 as the imaging target are acquired, it is ideal that the location information of the contour point T of the pillar PL1 specified in the predetermined orientation angle θ of any piece of image data IM is the same. However, in practice, the location information of the contour point T specified by each image data IM varies in many cases. Although the details will be described later, the analysis unit 25 calculates such variation in the location information of the contour point T as the standard deviation σ in advance. The analysis unit 25 defines a value obtained by taking the reciprocal number of the calculated standard deviation σ as the weight W. Therefore, for example, the smaller the variation in the location information of the contour point T, the larger the weight W.

The weighting table 200 is a table in which the weight W calculated for each orientation angle θ and the index ID are associated with each other. Details of the calculating method of the weight W and the generating method of the weighting table 200 will be described later.

When the second contour point group data generation unit 24 generates the second contour point group data 300, a random extraction method based on the first contour point group data 100 and the weighting table 200 is used. By using the random extraction method based on the weight W, the contour point T having a large weight W, that is, having a small variation in the location information is extracted from the first contour point group data 100 with a high probability. In this manner, the second contour point group data 300 is generated. Details of the random extraction method based on the weight W will be described later.

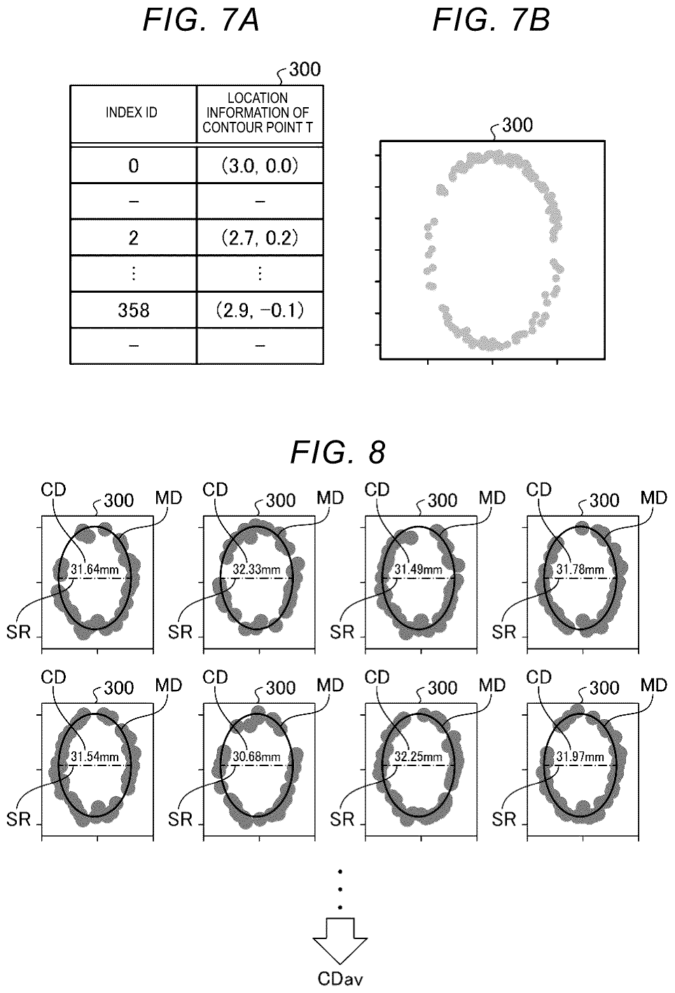

FIGS. 7A and 7B are diagrams showing an example of the second contour point group data 300 according to the embodiment. The example in FIG. 7A represents the generated second contour point group data 300 in a table. In addition, the example of FIG. 7B represents the second contour point group data 300 of FIG. 7A on the coordinates.

The example shown in FIGS. 7A and 7B shows an example in which the location information of a predetermined number of, for example, 180 contour points T is extracted from the first contour point group data 100 shown in the example of FIG. 5A by the random extraction method based on the weight W. The second contour point group data 300 including the location information of the 180 contour points T includes the contour points T having a small variation in the location information with a high probability.

The second contour point group data generation unit 24 repeatedly executes the generation of the second contour point group data 300 described above a plurality of times. A random extraction method is used for the generation of the second contour point group data 300. Therefore, the plurality of pieces of generated second contour point group data 300 are different from each other. In this manner, a plurality of different pieces of second contour point group data 300 are generated from one image data IM.

Returning to FIG. 1, the analysis unit 25 calculates the dimension CD of, for example, the minor axis SA of the pillar PL1, based on the plurality of pieces of generated second contour point group data 300. The dimension CD is an example of measurement data.

FIG. 8 is a diagram illustrating the calculation of the dimension CD in the embodiment.

FIG. 8 shows a plurality of pieces of generated second contour point group data 300. Specifically, the analysis unit 25 performs model fitting based on each of the plurality of pieces of second contour point group data 300 and the model MD. Accordingly, in each of the plurality of pieces of second contour point group data 300, the dimension CD of the minor axis SA of the pillar PL1 is defined. As described above, the second contour point group data 300 includes many contour points T having a small variation in the location information. Therefore, the dimension CD can be defined with higher accuracy. The analysis unit 25 calculates the average value CDav based on the defined dimension CD. The average value CDav is an example of a representative value.

The determination unit 26 determines whether the calculated average value CDav is within the reference range. The reference is, for example, predetermined based on design information of the pillar PL1 or the like, and is input to the shape measurement device 20 by the input unit 206. The determination unit 26 outputs the determination result to the output unit 205.

FIG. 9 is a block diagram illustrating an example of a hardware configuration of the shape measurement device 20 according to the embodiment. The shape measurement device 20 exemplified here is provided with a microcomputer (processor) to which a central processing unit (CPU) 201, a read-only memory (ROM) 202, a random-access memory (RAM) 203, an external storage device 204, an output unit 205, an input unit 206, and the like are connected via a bus 207. The CPU 201 executes various types of shape measurement processing in accordance with a program stored in the ROM 202, the external storage device 204, and the like. The RAM 203 is used as a work area or the like of the CPU 201. The output unit 205 may be, for example, a display, a speaker, or the like. The input unit 206 may be, for example, a keyboard, a touch panel mechanism, a pointing device, or the like. The hardware configuration of the shape measurement device 20 is not limited to the above description, and may be configured using a device such as an application specific integrated circuit (ASIC) or a field programmable gate array (FPGA).

### Manufacturing Method of Semiconductor Device

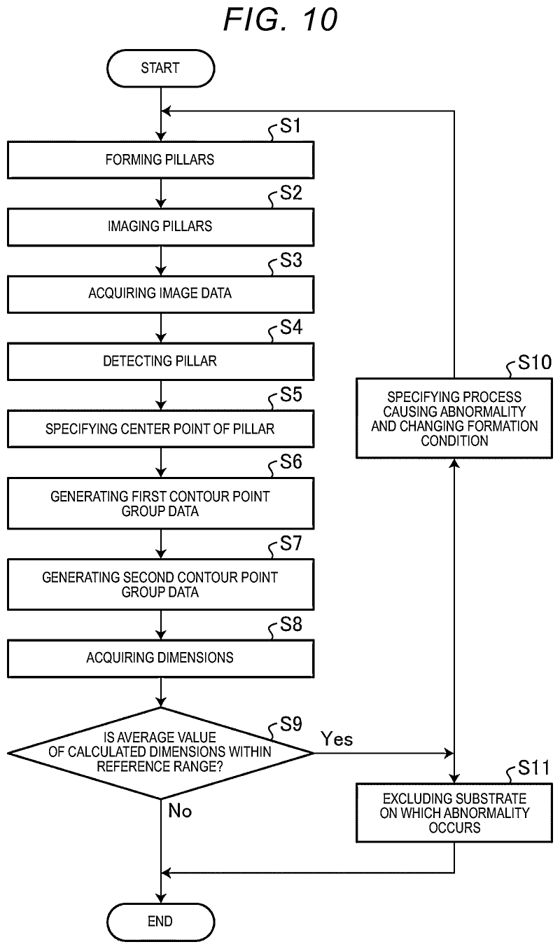

Next, a manufacturing method of a semiconductor device according to the embodiment will be described with reference to FIGS. 10 to 13. The substrate described with reference to FIGS. 10 to 13 corresponds to the sample S that is an observation target of the pattern shape measurement system 1. In the examples of FIGS. 10 to 13, as one step of the manufacturing method of a semiconductor device, an example in which a shape measurement processing for the pillar PL1 formed on the substrate is performed with the substrate as an observation target will be described.

FIG. 10 is a flowchart showing an example of a procedure of the manufacturing method of a semiconductor device according to the embodiment.

The pillars PL1 to PL12 are formed on the substrate under predetermined formation conditions (S1).

When the substrate is placed on a stage 261 of the electron image capturing device 10, the electron image capturing device 10 scans the observation region R with the electron beam EB and images the observation region R. As a result, image data IM of the pillars PL1 to PL12 is generated (S2).

Next, a step of performing shape measurement processing on the pillar PL1 as a target pattern among the pillars PL1 to PL12 will be described. The shape measurement processing of the pillar PL1 in the shape measurement device 20 is performed as a part of the manufacturing method of a semiconductor device.

The image acquisition unit 21 acquires the image data IM from the electron image capturing device 10 (S3).

The pattern detection unit 22 detects the pillar PL1 (S4). In addition, the pattern detection unit 22 specifies the center point C1 of the pillar PL1 (S5).

The first contour point group data generation unit 23 generates the first contour point group data 100 (S6). Specifically, the first contour point group data generation unit 23 specifies the contour point T of the pillar PL1 present on the orientation line DL having the orientation angle θ from the reference line BL passing through the center point C1 based on the image data IM. The first contour point group data generation unit 23 specifies the contour point T in each of the orientation lines DL extending in all orientations from the reference line BL. The first contour point group data generation unit 23 associates the location information of the specified contour point T with the index ID. As a result, the first contour point group data 100 is generated.

The second contour point group data generation unit 24 generates the second contour point group data 300 according to the weight W (S7). The generated first contour point group data 100 and the weighting table 200 are used for the generation of the second contour point group data 300.

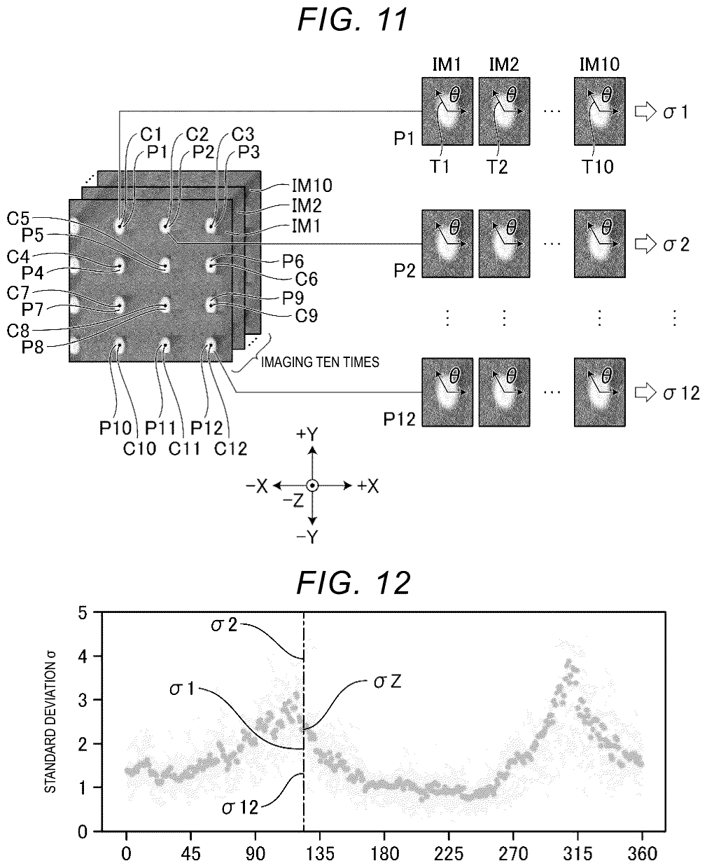

Here, a detailed description will be given of a calculating method of the weight W and a generating method of the weighting table 200 with reference to FIGS. 11 and 12. FIG. 11 is a diagram illustrating an example of a procedure of a generating method of the weighting table 200 according to the embodiment.

The weighting table 200 is generated in advance in the pattern shape measurement system 1 and stored in the memory unit 27 before the shape measurement processing of the pillar PL1.

As shown in FIG. 11, the electron image capturing device 10 generates image data IM including pillars PL1 to PL12. Specifically, the electron image capturing device 10 generates 10 image data IM1 to IM10 by repeating the imaging of the pillars PL1 to PL12, for example, 10 times.

The image acquisition unit 21 acquires the image data IM1 to IM10. The pattern detection unit 22 detects the pillars PL1 to PL12 for each of the image data IM1 to IM10 and specifies the center points C1 to C12 of the detected pillars PL1 to PL12.

The first contour point group data generation unit 23 defines the reference line BL for, for example, the pillar PL1 included in each of the image data IM1 to IM10 and specifies the location information of the contour points Ti to T10 in the orientation angle θ.

The analysis unit 25 calculates the standard deviation al of the location information of the contour points Ti to T10 in the orientation angle θ based on the location information of the specified contour points Ti to T10.

The analysis unit 25 executes the same procedure as described above for the pillars PL2 to 12 and calculates the standard deviations σ2 to σ12 of the location information of the contour points T in the orientation angle θ.

The analysis unit 25 calculates the standard deviations σ1 to σ12 based on the location information of the contour points Ti to T10 specified in all orientations from the reference line BL. The standard deviations σ1 to σ12 of the location information of the contour points T in all orientations calculated by the above procedure are shown in FIG. 12.

FIG. 12 is a diagram illustrating the standard deviation σ of the location information of the contour point T according to the embodiment. In FIG. 12, the horizontal axis represents the orientation angle θ, and the vertical axis represents the standard deviation σ. In FIG. 12, the plots shaded in gray show the values of the standard deviations σ1 to σ12 at each orientation angle θ, and the plots shaded in black show the median values σZ of the standard deviations σ1 to σ12.

As shown in FIG. 12, the standard deviation σ increases as the orientation angle θ approaches approximately 1280 and approximately 308°, and decreases as the orientation angle θ moves away from approximately 1280 and approximately 308°. Here, the inventors found that the tendency of the standard deviation σ has a correlation with the scanning direction of the electron beam EB as follows.

FIG. 13 is a diagram illustrating the standard deviation σ in FIG. 12 in a radar chart. In FIG. 13, an axis in a radial direction indicates the standard deviation σ, and an axis in a circumferential direction indicates the orientation angle θ.

An axis Ax extending in the positive direction of X from the center point O in FIG. 13 indicates an orientation angle θ=0°. That is, the direction in which the axis Ax of FIG. 13 extends corresponds to the direction in which the reference line BL of the pillars PL1 to PL12 defined in the image data IM extends. In addition, the contour line L is a line connecting the median values σZ of the standard deviation σ of the contour points T in all orientations from the reference line BL. An arrow N directed in a predetermined direction between the positive direction of X and the positive direction of Y in FIG. 13 corresponds to the scanning direction of the electron beam EB described with reference to FIGS. 2 and 3.

As shown in FIG. 13, at the orientation angle θ of approximately 128° and approximately 308° in which the standard deviation σ is maximized, the contour line L extends along the scanning direction of the electron beam EB. That is, the standard deviation σ shows a maximum value at the orientation angle θ when the contour line L is along the scanning direction of the electron beam EB. In addition, the standard deviation σ has a relatively small value at the orientation angle θ when the contour line L intersects the scanning direction of the electron beam EB.

As described above, the inventors have found that the standard deviation σ of the location information of the contour point T of the pillar PL varies depending on the orientation angle θ, and the standard deviation σ tends to increase at a predetermined orientation angle θ. The inventor also found that this tendency is correlated with the scanning direction of the electron beam EB.

Returning to FIG. 10, the description will be continued.

In S7, when the second contour point group data 300 is generated, the second contour point group data generation unit 24 uses a random extraction method based on the weight W.

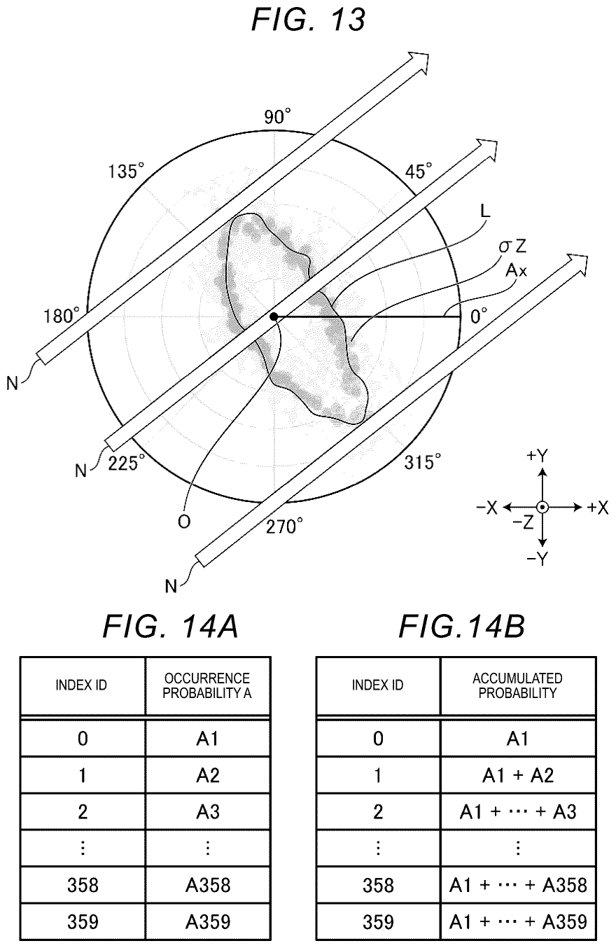

FIGS. 14A and 14B are diagrams illustrating random extraction based on the weight W in the embodiment. FIG. 14A shows the weight W converted into the occurrence probability based on the weighting table 200 shown in FIG. 6. Further, FIG. 14B is a diagram in which the occurrence probability in FIG. 14A is accumulated for each index ID.

Specifically, as shown in FIG. 14A, the second contour point group data generation unit 24 calculates a ratio of the weight W, which is associated with each of the indexes ID1 to ID359, to the total of the weight W as the occurrence probability A based on the weighting table 200 shown in FIG. 6.

As shown in FIG. 14B, the second contour point group data generation unit 24 accumulates the occurrence probabilities A1 to A359 in the order of the indexes ID and assigns the accumulated probabilities as the accumulated weight to the indexes ID.

Next, the second contour point group data generation unit 24 randomly generates a predetermined number of random numbers X. The random number X is a random number of less than 1, which is the total of the occurrence probabilities A1 to A359. In other words, the random number X is generated based on the weight W. The second contour point group data generation unit 24 collates the generated random number X with the accumulated probability in FIG. 14B and extracts the index ID corresponding to the accumulated probability including the random number X. Specifically, for example, when the generated random number X is less than A1, “1” is extracted as the index ID. In addition, for example, when the generated random number X is equal to or more than A1 and less than A1+A2, “2” is extracted as the index ID. As a result, the index ID having a large weight W is extracted with a high probability.

The second contour point group data generation unit 24 executes the above-described extraction for the predetermined number of random numbers X. As a result, the predetermined number of indexes ID are extracted. Here, the predetermined number is, for example, 180. In order to avoid duplication of the extracted indexes ID, when the index ID extracted by the second and subsequent random numbers X is the index ID extracted already, processing such as skipping the extraction may be performed.

The second contour point group data generation unit 24 extracts the location information of the contour point T corresponding to the index ID extracted by the above-described processing from the first contour point group data 100. As a result, the second contour point group data 300, in which the location information of the contour point T having large weight W is included with a high probability, is generated.

The second contour point group data generation unit 24 generates the second contour point group data 300 a predetermined number of times. As a result, a plurality of different pieces of second contour point group data 300 are generated. The predetermined number of times is, for example, 200 times.

The analysis unit 25 acquires a plurality of dimensions CD for the pillar PL1 by performing model fitting on each of the plurality of pieces of generated second contour point group data 300 (S8).

The analysis unit 25 calculates an average value CDav as a representative value from the plurality of dimensions CD. The representative value is not limited to the average value Dav. For example, the median value or the mode of the plurality of CD dimensions may be used.

The determination unit 26 determines whether the average value CDav of the calculated dimensions CD of the pillars PL1 is within the reference range (S9).

When the determination unit 26 determines that the average value CDav is not within the reference range (S9—YES), the processing proceeds to S10.

When the determination unit 26 determines that the average value CDav is not within the reference range, the process causing the average value CDav to exceed the reference is specified, and the formation condition of the pillar PL1 is changed (S10). Then, the substrate on which the abnormality occurs is excluded (S11).

When the determination unit 26 determines that the average value CDav is within the reference range (S9—NO), the processing is ended.

In this manner, the shape measurement processing of the pillar PL in the shape measurement device 20 is ended, and the semiconductor device of the embodiment is manufactured.

### Overview

According to the pattern shape measurement method of the embodiment, the first contour point group data 100 in which the location information of the contour point T of the pillar PL extracted based on the image data IM and the index ID related to the orientation angle θ from the reference line BL are associated with each other is generated. Then, the second contour point group data 300 according to the weight W is generated based on the weighting table 200 and the first contour point group data 100. In the weighting table 200, the index ID and the weight W based on the standard deviation σ of the location information of the contour point T of the pillar PL present in the orientation angle θ are associated with each other.

As described above, the second contour point group data 300 including the contour points T based on the magnitude of the weight W is generated from the first contour point group data 100. Accordingly, the shape of the pillar PL can be measured with high accuracy.

According to the pattern shape measurement method of the embodiment, when creating the second contour point group data 300, the extraction of the index ID corresponding to the random number X generated based on the weight W is repeatedly performed. Based on the plurality of pieces of second contour point group data 300 generated in this way, a plurality of dimensions CD are acquired, and an average value is calculated from the plurality of dimensions CD.

As described above, the random extraction based on the magnitude of the weight W is performed from the first contour point group data 100, and thus a plurality of different pieces of second contour point group data 300 are generated. As a result, the shape of the pillar PL can be measured with higher accuracy.

### Modification Example

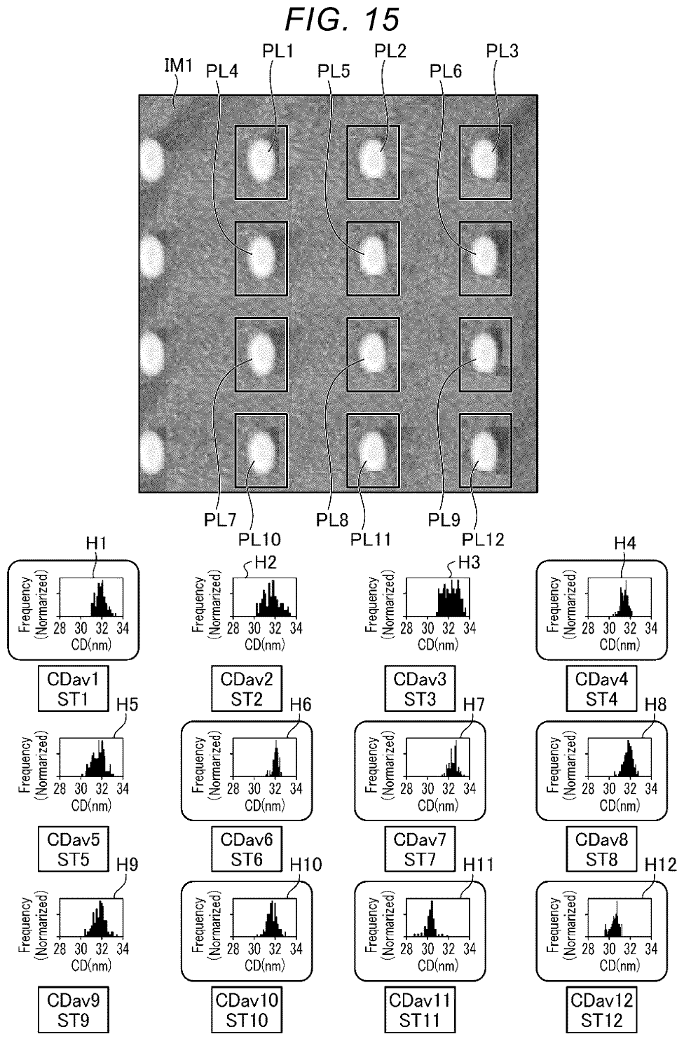

A pattern shape measurement method of the modification example will be described with reference to FIG. 15. The pattern shape measurement method of the modification example is different from that of the above-described embodiment in that the shape measurement processing is executed by selecting the pillar PL having a small variation in the dimension CD from the pillars PL1 to PL12 included in the image data IM.

FIG. 15 is a diagram illustrating an example of a procedure of a pattern shape measurement method according to the modification example. FIG. 15 shows histograms H1 to H12 based on the dimension CD acquired for each of the pillars PL1 to PL12.

Before the description of the pattern shape measurement method of the modification example, it is assumed that the processing of S4 to S8 are executed for each of the pillars PL1 to PL12 of the image data IM acquired in S3 in FIG. 10.

The analysis unit 25 calculates the average values CDav1 to CDav12 based on the plurality of acquired dimensions CD for each of the pillars PL1 to PL12 as the target pattern.

In addition, the analysis unit 25 calculates the standard deviations ST1 to ST12 based on the plurality of dimensions CD acquired for each of the pillars PL1 to PL12. The standard deviations ST1 to ST12 are an example of the degree of dispersion. The degree of dispersion is not limited to the standard deviation ST. For example, the degree of dispersion may be a range.

The analysis unit 25 selects a predetermined number of pillars PL from pillars PL1 to PL12 in ascending order of the calculated standard deviation ST. For example, in the example shown in FIG. 15, the analysis unit 25 selects eight pillars PL of pillars PL1, PL4, PL6, PL7, PL8, PL10, PL11, and PL12 in ascending order of the standard deviation ST. The number of pillars PL is not limited thereto.

The analysis unit 25 calculates the average value of the selected eight pillars PL as the measurement value of the observation region R. Since the average value CDav of the pillars PL with the smaller standard deviation ST is adopted, the shape of the pillar PL can be measured with higher accuracy.

According to the pattern shape measurement method of the modification example, other effects similar to those of the pattern shape measurement method and the pattern shape measurement device of the above-described embodiment are obtained.

### Another Modification Example

In the above-described embodiment and modification example, the pattern shape measurement system 1 is described as being provided with the electron image capturing device 10 and the shape measurement device 20, but the present disclosure is not limited thereto. For example, the electron image capturing device 10 may be provided with the shape measurement device 20.

In the above-described embodiment and modification example, the location where the luminance is maximum is specified as the contour point T among the generated luminance profiles, but the present disclosure is not limited thereto. Among the luminance profiles, a location satisfying a predetermined condition may be specified as the contour point T.

In the above-described embodiment and modification example, the orientation angle θ is incremented by 1° from the reference line BL, and the index ID is associated with each of the orientation angles θ, but the present disclosure is not limited thereto. For example, as the increment of the orientation angle θ is smaller, the measurement can be performed with higher accuracy.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A pattern shape measurement method comprising:
acquiring image data of a target pattern obtained by irradiating an observation region of a sample with a charged particle or an electromagnetic wave;
generating first contour point group data in which location information of a contour point of the target pattern extracted based on the image data and an index related to an orientation angle of a line connecting a center of the target pattern and the contour point from a reference line passing through the center of the target pattern are associated with each other; and
generating, based on a weighting table, in which the index and weight determined based on a standard deviation of location information of the contour point of the target pattern present in a direction of the orientation angle are associated with each other and stored, and the first contour point group data and the second contour point group data, according to the weight.

2. The pattern shape measurement method according to claim 1,
wherein the generating the second contour point group data according to the weight includes (i) generating a random number based on the weight, (ii) repeatedly extracting the index corresponding to the random number from the weighting table, and (iii) generating a plurality of pieces of second contour point group data using the location information of the contour point corresponding to the extracted index among the first contour point group data, and
the pattern shape measurement method further comprises:
acquiring a plurality of pieces of measurement data by performing fitting for each of the plurality of pieces of generated second contour point group data; and
calculating a representative value from the plurality of pieces of measurement data.

3. The pattern shape measurement method according to claim 2,
wherein, when the observation region includes a plurality of target patterns,
the measurement data is acquired for each of the plurality of target patterns,
a degree of dispersion for each of the plurality of target patterns and the representative value are acquired based on the measurement data,
a predetermined number of target patterns are selected from the plurality of target patterns in ascending order of the acquired degree of dispersion, and
a measurement value of the observation region is calculated from the representative value of the selected target pattern.

4. The pattern shape measurement method according to claim 2,
wherein the representative value is any one of an average value, a median value, and a mode.

5. The pattern shape measurement method according to claim 3,
wherein the degree of dispersion is any one of range and a standard deviation.

6. The pattern shape measurement method according to claim 2,
wherein the extracting the index corresponding to the random number includes:
extracting, by collating accumulated weight, which is assigned for each of the indexes and is obtained by accumulating the weight corresponding to the index in an order, with the random number generated based on a total of the weight, the index corresponding to the accumulated weight including the random number.

7. A pattern shape measurement device comprising:
an image acquisition circuit configured to acquire image data of a target pattern obtained by irradiating an observation region of a sample with a charged particle or an electromagnetic wave;
a first contour point group data generation circuit configured to generate first contour point group data in which location information of a contour point of the target pattern extracted based on the image data and an index related to an orientation angle of a line connecting a center of the target pattern and the contour point from a reference line passing through the center of the target pattern are associated with each other;
a memory configured to store a weighting table in which the index and weight determined based on a standard deviation of location information of the contour point of the target pattern present in a direction of the orientation angle are associated with each other; and
a second contour point group data generation circuit configured to generate second contour point group data according to the weight based on the weighting table, and the first contour point group data.

8. A manufacturing method of a semiconductor device comprising:
forming a target pattern on a substrate in a predetermined formation condition;
irradiating an observation region of the substrate with a charged particle or an electromagnetic wave and imaging the target pattern with an imaging device;
acquiring image data of the imaged target pattern;
generating first contour point group data in which location information of a contour point of the target pattern extracted based on the image data and an index related to an orientation angle of a line connecting a center of the target pattern and the contour point from a reference line passing through the center of the target pattern are associated with each other;
generating, based on a weighting table in which the index and weight determined based on a standard deviation of location information of the contour point of the target pattern present in a direction of the orientation angle are associated with each other and stored, and the first contour point group data, and the second contour point group data, according to the weight;
determining whether measurement data of the target pattern acquired based on the second contour point group data is within a reference range; and
changing the formation condition of the target pattern to an appropriate condition based on the measurement data when it is determined that the measurement data is not within the reference range.

9. A non-transitory storage medium storing a program, which when executed by a computer, performs a pattern shape measurement method comprising:
acquiring image data of a target pattern obtained by irradiating an observation region of a sample with a charged particle or an electromagnetic wave;
generating first contour point group data in which location information of a contour point of the target pattern extracted based on the image data and an index related to an orientation angle of a line connecting a center of the target pattern and the contour point from a reference line passing through the center of the target pattern are associated with each other; and
generating, based on a weighting table, in which the index and weight determined based on a standard deviation of location information of the contour point of the target pattern present in a direction of the orientation angle are associated with each other and stored, and the first contour point group data and the second contour point group data, according to the weight.

10. The non-transitory storage medium according to claim 9, wherein the pattern shape measurement method further comprises:
wherein the generating the second contour point group data according to the weight includes (i) generating a random number based on the weight, (ii) repeatedly extracting the index corresponding to the random number from the weighting table, and (iii) generating a plurality of pieces of second contour point group data using the location information of the contour point corresponding to the extracted index among the first contour point group data, and
the pattern shape measurement method further comprises:
acquiring a plurality of pieces of measurement data by performing fitting for each of the plurality of pieces of generated second contour point group data; and
calculating a representative value from the plurality of pieces of measurement data.

11. The non-transitory storage medium according to claim 9, wherein the pattern shape measurement method further comprises:
wherein, when the observation region includes a plurality of target patterns,
the measurement data is acquired for each of the plurality of target patterns,
a degree of dispersion for each of the plurality of target patterns and the representative value are acquired based on the measurement data,
a predetermined number of target patterns are selected from the plurality of target patterns in ascending order of the acquired degree of dispersion, and
a measurement value of the observation region is calculated from the representative value of the selected target pattern.

12. The non-transitory storage medium according to claim 9, wherein the representative value is any one of an average value, a median value, and a mode.

13. The non-transitory storage medium according to claim 10, wherein the degree of dispersion is any one of range and a standard deviation.

14. The non-transitory storage medium according to claim 10, wherein the extracting the index corresponding to the random number includes:
extracting, by collating accumulated weight, which is assigned for each of the indexes and is obtained by accumulating the weight corresponding to the index in an order, with the random number generated based on a total of the weight, the index corresponding to the accumulated weight including the random number.
